(19) United States
(12) Patent Application Publication
(10) Pub. No.: US 2025/0098252 A1
(43) Pub. Date: Mar. 20, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Ke-Ting Chen, Tainan City (TW); Ching-Ling Lin, Kaohsiung City (TW); Wen-An Liang, Tainan City (TW); Chia-Fu Hsu, Tainan City (TW)

(73) Assignee: UNITED MICROELECTRONICS CORP., Hsin-Chu City (TW)

(21) Appl. No.: 18/379,667

(22) Filed: Oct. 13, 2023

(30) Foreign Application Priority Data
Sep. 20, 2023 (TW) 112135883

(51) Int. Cl. H01L 29/40; H01L 21/311; H01L 29/417; H01L 29/423

(52) U.S. Cl. CPC H10D 64/01; H01L 21/31144; H10D 64/251; H10D 64/511

(57) ABSTRACT

A method for fabricating a semiconductor device includes the steps of forming a metal gate on a substrate, a contact etch stop layer (CESL) adjacent to the metal gate, and an interlayer dielectric (ILD) layer around the gate structure, performing a first etching process to remove the ILD layer, performing a second etching process to remove the CESL for forming a first contact hole, and then forming a first contact plug in the first contact hole. Preferably, a width of the first contact plug adjacent to the CESL is less than a width of the first contact plug under the CESL.

### BACKGROUND OF THE INVENTION

### 1. Field of the Invention

The invention relates to a method for fabricating semiconductor device, and more particularly, to a method of forming contact plugs through multistage etching processes.

### 2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

In current FinFET fabrication, a photo-etching process is typically conducted to remove part of the ILD layer for forming contact holes after polysilicon gates are transformed into metal gates through a replacement metal gate (RMG) process and then conductive materials are deposited into the contact holes for forming contact plugs. Nevertheless, epitaxial layers are often lost during formation of the contact holes thereby affecting operation of the device. Hence how to improve the current FinFET fabrication and structure has become an important task in this field.

### SUMMARY OF THE INVENTION

According to an embodiment of the present invention, a method for fabricating a semiconductor device includes the steps of forming a metal gate on a substrate, a contact etch stop layer (CESL) adjacent to the metal gate, and an interlayer dielectric (ILD) layer around the gate structure, performing a first etching process to remove the ILD layer, performing a second etching process to remove the CESL for forming a first contact hole, and then forming a first contact plug in the first contact hole. Preferably, a width of the first contact plug adjacent to the CESL is less than a width of the first contact plug under the CESL.

According to another aspect of the present invention, a semiconductor device includes a metal gate on a substrate, a contact etch stop layer (CESL) adjacent to the metal gate, an interlayer dielectric (ILD) layer around the CESL, and a first contact plug in the ILD layer. Preferably, a width of the first contact plug adjacent to the CESL is less than a width of the first contact plug under the CESL.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a semiconductor device according to an embodiment of the present invention.

### DETAILED DESCRIPTION

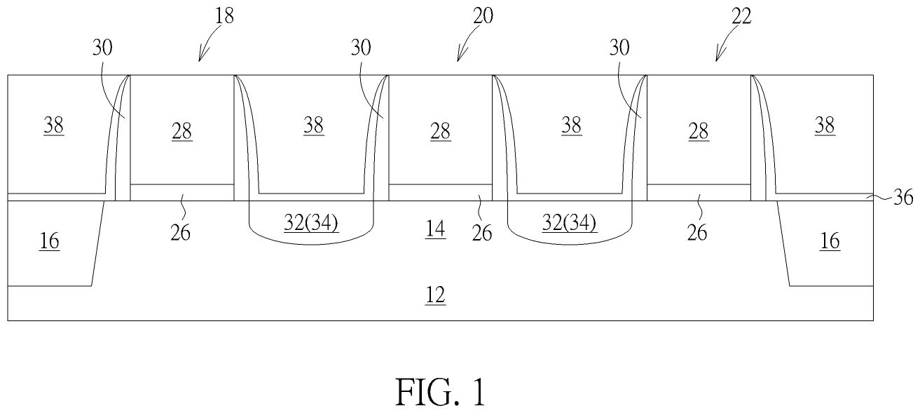

Referring to FIGS. 1-7, FIGS. 1-7 illustrate a method for fabricating a semiconductor device according to an embodiment of the present invention. As shown in FIG. 1, a substrate 12 such as a silicon substrate or silicon-on-insulator (SOI) substrate is first provided, and one or more fin-shaped structures 14 are formed on the substrate 12. Preferably, it would be desirable to adjust the number of fin-shaped structures 14 depending on the demand of the product, which is also within the scope of the present invention.

Preferably, the fin-shaped structures 14 of this embodiment could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures 14 could also be obtained by first forming a patterned mask (not shown) on the substrate, 12, and through an etching process, the pattern of the patterned mask is transferred to the substrate 12 to form the fin-shaped structures 14. Moreover, the formation of the fin-shaped structures 14 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structures 14. These approaches for forming fin-shaped structures 14 are all within the scope of the present invention.

Next, a shallow trench isolation (STI) 16 is formed around the fin-shaped structures 14. In this embodiment, the formation of the STI 16 could be accomplished by conducting a flowable chemical vapor deposition (FCVD) process to form a silicon oxide layer on the substrate 12 and covering the fin-shaped structures 14 entirely. Next, a chemical mechanical polishing (CMP) process along with an etching process are conducted to remove part of the silicon oxide layer so that the top surface of the remaining silicon oxide is even with or slightly lower than the top surface of the fin-shaped structures 14 for forming the STI 16.

Next, gates structures 18, 20, 22 or dummy gates are formed on the fin-shaped structure 14. In this embodiment, the formation of the gate structures 18, 20, 22 could be accomplished by a gate first process, a high-k first approach from gate last process, or a high-k last approach from gate last process. Since this embodiment pertains to a high-k last approach, a gate dielectric layer 26 or interfacial layer, a gate material layer 28 made of polysilicon, and a selective hard mask could be formed sequentially on the substrate 12, and a photo-etching process is then conducted by using a patterned resist (not shown) as mask to remove part of the gate material layer 28 and part of the gate dielectric layer 26 through single or multiple etching processes. After stripping the patterned resist, gate structures 18, 20, 22 each composed of a patterned gate dielectric layer 26 and a patterned material layer 28 are formed on the fin-shaped structure 14.

Next, at least a spacer 30 is formed on the sidewalls of the each of the gate structures 18, 20, 22, a source/drain region 32 and/or epitaxial layer 34 is formed in the fin-shaped structure 14 and/or substrate 12 adjacent to two sides of the spacer 30, and selective silicide layers (not shown) could be formed on the surface of the source/drain regions 32. Since the source/drain region 32 is only formed in the substrate 12 adjacent to two sides of the gate structure 20, the gate structure 20 preferably functions as an active gate while the two adjacent gate structures 18, 22 are dummy gates. In this embodiment, the spacer 30 could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The source/drain region 32 and epitaxial layer 34 could include different dopants or different material depending on the type of transistor being fabricated. For instance, the source/drain region 32 could include p-type or n-type dopants and the epitaxial layer 34 could include SiGe, SiC, or SiP.

In this embodiment, the epitaxial layer 34 could also be formed to include different materials depending on the type of transistor being fabricated. For instance, if the MOS transistor being fabricated were to be a PMOS transistor, the epitaxial layer 34 could be made of material including but not limited to for example SiGe, SiGeB, or SiGeSn. If the MOS transistor being fabricated were to be a NMOS transistor, the epitaxial layer 34 could be made of material including but not limited to for example SiC, SiCP, or SiP. Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layers 44 are preferred to have less or no germanium atom at all to facilitate the formation of silicide afterwards.

According to an embodiment of the present invention, it would also be desirable to form the source/drain region 32 in part or all of the epitaxial layer 34. According to another embodiment of the present invention, the source/drain region 32 could also be formed insituly during the SEG process. For instance, the source/drain region 32 could be formed by implanting p-type dopants during formation of a SiGe epitaxial layer, a SiGeB epitaxial layer, or a SiGeSn epitaxial layer for PMOS transistor, or could be formed by implanting n-type dopants during formation of a SiC epitaxial layer, SiCP epitaxial layer, or SiP epitaxial layer for NMOS transistor. By doing so, it would be desirable to eliminate the need for conducting an extra ion implantation process for forming the source/drain region 32. Moreover, the dopants within the source/drain region 32 could also be formed with a gradient, which is also within the scope of the present invention.

Next, a contact etch stop layer (CESL) 36 is formed on the gate structures 18, 20, 22 and the STI 16 and an interlayer dielectric (ILD) layer 38 is formed on the CESL 36. Next, a planarizing process such as CMP is conducted to remove part of the ILD layer 38 and part of the CESL 36 for exposing the gate material layer 28 made of polysilicon so that the top surface of the gate material layer 28 is even with the top surface of the ILD layer 38.

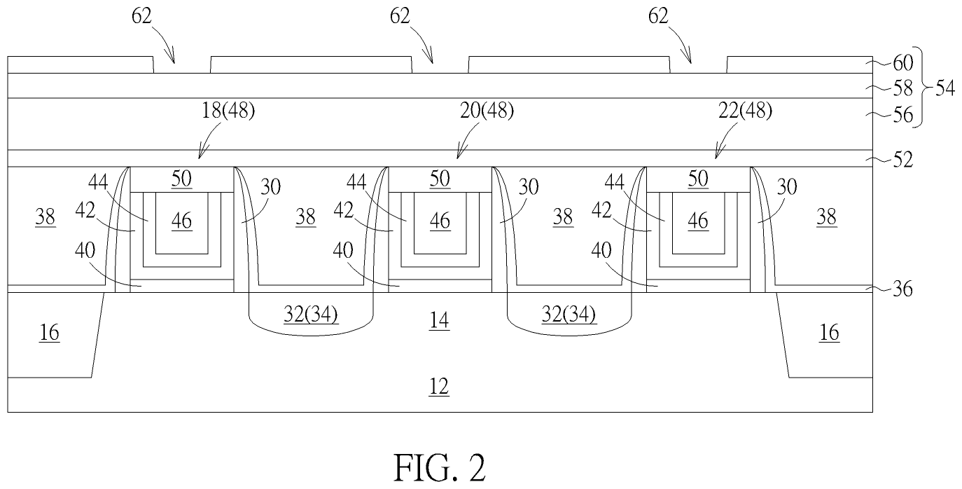

Next, as shown in FIG. 2, a replacement metal gate (RMG) process is conducted to transform the gate structures 18, 20, 22 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 28 and even the gate dielectric layer 26 from each of the gate structures 18, 20, 22 for forming recesses (not shown) in the ILD layer 38.

Next, a selective interfacial layer 40 or gate dielectric layer, a high-k dielectric layer 42, a work function metal layer 44, and a low resistance metal layer 46 are formed in the recesses, and a planarizing process such as CMP is conducted to remove part of low resistance metal layer 46, part of work function metal layer 44, and part of high-k dielectric layer 42 to form metal gates 48. In this embodiment, each of the gate structures or metal gates 48 fabricated through high-k last process of a gate last process preferably includes an interfacial layer 40 or gate dielectric layer, a U-shaped high-k dielectric layer 42, a U-shaped work function metal layer 44, and a low resistance metal layer 46.

In this embodiment, the high-k dielectric layer 42 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 44 is formed for tuning the work function of the metal gate in accordance with the conductivity of the device. For an NMOS transistor, the work function metal layer 44 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 44 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 44 and the low resistance metal layer 46, in which the material of the barrier layer may include titanium (Ti), titanium nitride (TiN), tantalum (Ta) or tantalum nitride (TaN). Furthermore, the material of the low-resistance metal layer 46 may include copper (Cu), aluminum (Al), titanium aluminum (TiAl), cobalt tungsten phosphide (CoWP) or any combination thereof.

Next, part of the high-k dielectric layer 42, part of the work function metal layer 44, and part of the low resistance metal layer 46 could be removed to form recesses (not shown), a hard mask 50 is formed into each of the recesses, and a planarizing process is conducted so that the top surface of the hard mask 50 is even with the top surface of the ILD layer 38. In this embodiment, the hard mask 50 could be selected from the group consisting of consisting of SiO₂, SiN, SiON, and SiCN.

Next, another hard mask 52 is formed on the top surface of the metal gates 48 and the ILD layer 38 and a patterned mask 54 is formed on the hard mask 52. In this embodiment, the hard mask 52 preferably includes tetraethyl orthosilicate (TEOS) and the patterned mask 54 includes an organic dielectric layer (ODL) 56, a silicon-containing hard mask bottom anti-reflective coating (SHB) 58, and a patterned resist 60, in which the patterned resist 60 includes openings 62 exposing the SHB 58 directly on top of the metal gates 48.

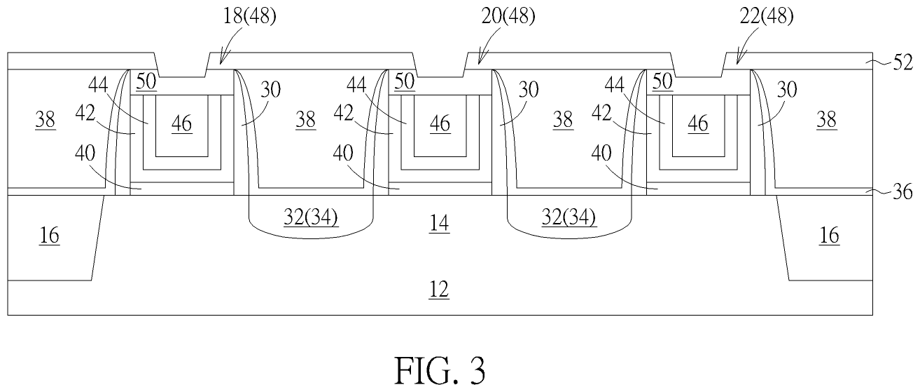

Next, as shown in FIG. 3, an etching process is conducted by using the patterned resist 60 as mask to remove part of the SHB 58, part of the ODL 56, part of the hard mask 52, and even part of the hard mask 50 for exposing the hard mask 50 directly on top of the metal gates 48. The patterned mask 54 is then removed to expose the surface of the hard mask 52 and hard mask 50.

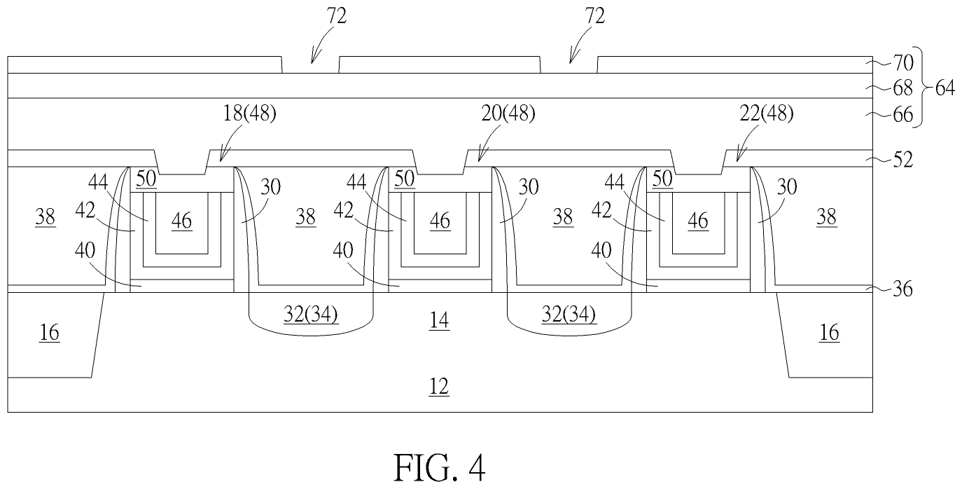

Next, as shown in FIG. 4, another patterned mask 64 is formed on the hard mask 52, in which the patterned mask 64 also includes an ODL 66, a SHB 68, and a patterned resist 70, in which the patterned resist 70 includes openings 72 exposing the SHB 68 directly on top of the source/drain region 32 or epitaxial layer 34.

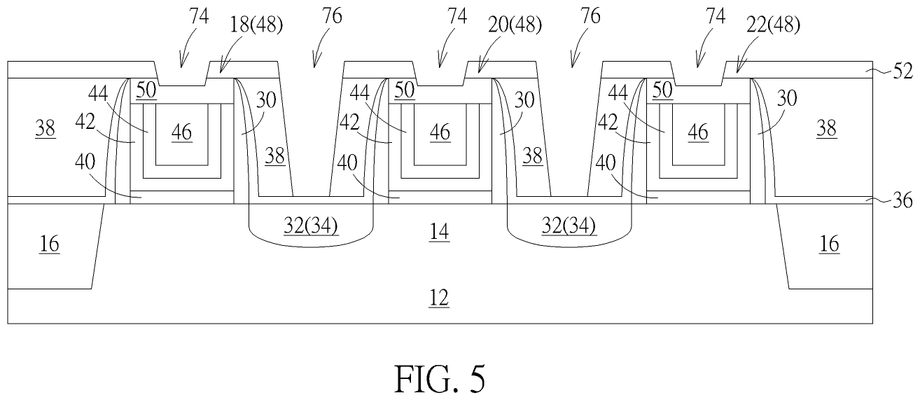

Next, as shown in FIG. 5, an etching process is conducted by using the patterned resist 70 as mask to remove part of the SHB 68, part of the ODL 66, part of the hard mask 52, and part of the ILD layer 38 directly on top of the source/drain region 32 and stop on the surface of the CESL 36. After removing the patterned mask 64, the hard mask 50 directly on top of the metal gates 48 and the hard mask 52 are exposed once more.

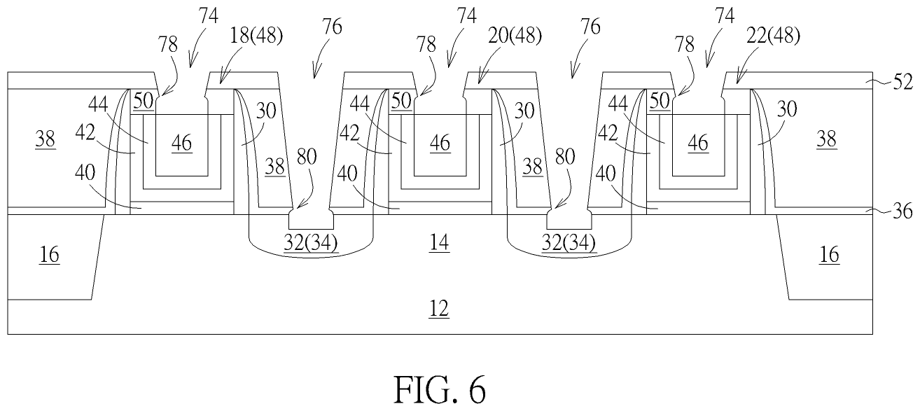

Next, as shown in FIG. 6, another etching process is conducted to remove part of the hard mask 50 directly on top of the metal gates 48 and part of the CESL 36 directly on top of the source/drain region 32 at the same for forming contact holes 74 exposing the top surface of the metal gates 48 and contact holes 76 exposing the surface of the source/drain region 32. Since the hard mask 50 and the CESL 36 are both made from SiN, no additional patterned mask is formed at this stage during the etching process for remove part of the hard mask 50 and part of the CESL 36 at the same time. Preferably, no metal gate 48 is removed during partial removal of the hard mask 50 while part of the epitaxial layer 34 could be removed during partial removal of the CESL 36.

It should also be noted that since a two stage or two step etching process is conducted at this stage for forming the contact holes 74, 76, sidewalls of each of the contact holes 74, 76 preferably demonstrate discontinuous profiles after part of the hard mask 50 and part of the CESL 36 are removed. Specifically, protrusions 78 or protruding portions are formed on sidewalls of the contact holes 74 or hard mask 50 directly on top of the metal gates 48 and protrusions 80 are formed on sidewalls of the contact holes 76 or CESL 36 directly on top of the source/drain region 32 or epitaxial layer 34. In detail, the width of the contact hole 76 immediately adjacent to the CESL 36 or between two adjacent CESLs 36 are slightly less than the width of the contact hole 36 in the epitaxial layer 34 or below the CESL 36.

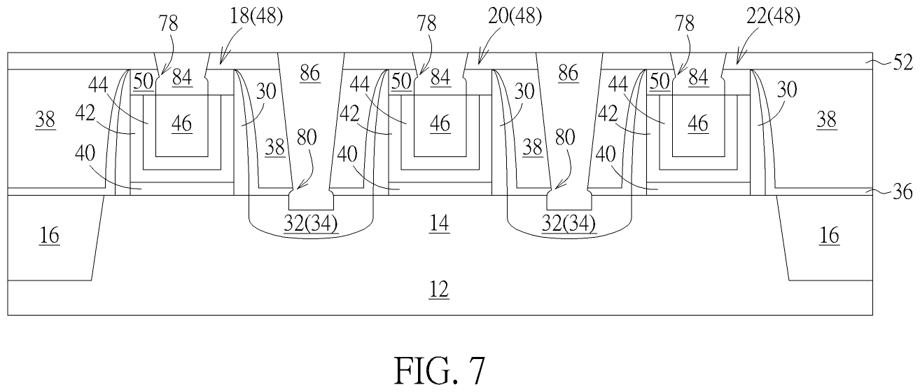

Next, as shown in FIG. 7, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes 74, 76, and a planarizing process such as CMP is conducted to remove part of aforementioned barrier layer and low resistance metal layer for forming contact plugs 84 in the contact holes 74 electrically connecting the metal gates 48 and contact plugs 86 in the contact holes 76 electrically connecting the source/drain region 32. This completes the fabrication of a semiconductor device according to an embodiment of the present invention.

Referring again to FIG. 7, FIG. 7 further illustrates a structural view of a semiconductor device according to an embodiment of the present invention. As shown in FIG. 7, the semiconductor device includes at least a metal gate 48 disposed on the substrate 12, a hard mask 50 disposed on the metal gate 48, a CESL 36 disposed adjacent to the metal gate 48, an ILD layer 38 surrounding the CESL 36, another hard mask 52 disposed on the hard mask 50 and the ILD layer 38, a contact plug 84 disposed directly on top of the metal gates 48, and another contact plug 86 disposed in the ILD layer 38 adjacent to the metal gate 48.

In this embodiment, each sidewall of the contact plug 84 directly on top of the metal gate 48 and each sidewall of the contact plug 86 adjacent to the metal gate 48 include a non-planar surface. Specifically, the contact plug 84 between the hard mask 50 includes a first width closer to the metal gate 84 and a second width closer to the hard mask 52, in which the second width is less than the first width. In other word, the second width between the protrusions 78 on sidewalls of the hard mask 50 is less than the first width underneath the protrusions 78.

Moreover, the width of the contact plug 86 immediately adjacent to the CESL 36 is preferably less than the width of the contact plug 86 underneath the CESL 36 and the width of the contact plug 86 immediately adjacent to the CESL 36 is also less than the width of the contact plug 86 above the CESL 36. In other words, the width of the contact plug 86 between the protrusions 80 of the CESL 36 is preferably less than the width of the contact plug 86 above or below the CESL 36.

Overall, the present invention first conducts a RMG process to transform a polysilicon gate into metal gate, conducts a first etching process to remove part of the ILD layer adjacent to the metal gate and stop on the surface of the CESL, and then conducts a second etching process to remove part of the hard mask directly on top of the metal gate and part of the CESL adjacent to the CESL at the same time to form contact plugs that expose the surface of the metal gate and the source/drain region and/or epitaxial layer simultaneously. Next, conductive materials are deposited into the contact holes to form contact plugs. By using the aforementioned two-stage etching process approach to fabricate contact plugs, it would be desirable to reduce damage and consumption of the epitaxial layers significantly and improve performance of the device substantially.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a metal gate on a substrate, a contact etch stop layer (CESL) adjacent to the metal gate, and an interlayer dielectric (ILD) layer around the gate structure;
performing a first etching process to remove the ILD layer; and
performing a second etching process to remove the CESL for forming a first contact hole.

2. The method of claim 1, further comprising:
forming a gate structure on a substrate;
forming a source/drain region adjacent to the gate structure;
forming the CESL adjacent to the gate structure;
forming the ILD layer around the CESL;
performing a replacement metal gate (RMG) process to transform the gate structure into the metal gate;
forming a first hard mask on the metal gate;
forming a second hard mask on the first hard mask and the ILD layer;
performing the first etching process to remove the second hard mask and the ILD layer;
performing the second etching process to remove the CESL and the first hard mask forming the first contact hole and a second contact hole; and
forming a first contact plug in the first contact hole and a second contact plug in the second contact hole.

3. The method of claim 2, wherein a width of the first contact plug adjacent to the CESL is less than a width of the first contact plug under the CESL.

4. The method of claim 2, wherein a width of the first contact plug adjacent to the CESL is less than a width of the first contact plug above the CESL.

5. The method of claim 2, wherein a sidewall of the first contact plug comprises a non-planar surface.

6. The method of claim 2, wherein the second contact plug between the first hard mask comprises:
a first width closer to the metal gate; and
a second width closer to the second hard mask.

7. The method of claim 6, wherein the second width is less than the first width.

8. The method of claim 2, wherein a sidewall of the second contact plug comprises a non-planar surface.

9. A semiconductor device, comprising:
a metal gate on a substrate;
a contact etch stop layer (CESL) adjacent to the metal gate;
an interlayer dielectric (ILD) layer around the CESL; and
a first contact plug in the ILD layer, wherein a width of the first contact plug adjacent to the CESL is less than a width of the first contact plug under the CESL.

10. The semiconductor device of claim 9, wherein a width of the first contact plug adjacent to the CESL is less than a width of the first contact plug above the CESL.

11. The semiconductor device of claim 9, wherein a sidewall of the first contact plug comprises a non-planar surface.

12. The semiconductor device of claim 9, further comprising:
a first hard mask on the metal gate, wherein top surfaces of the first hard mask and the ILD layer are coplanar;
a second hard mask on the first hard mask; and
a second contact plug on the metal gate.

13. The semiconductor device of claim 12, wherein the second contact plug between the first hard mask comprises:
a first width closer to the metal gate; and
a second width closer to the second hard mask.

14. The semiconductor device of claim 13, wherein the second width is less than the first width.

15. The semiconductor device of claim 12, wherein a sidewall of the second contact plug comprises a non-planar surface.
